(19) United States
(12) Patent Application Publication
(10) Pub. No.: US 2024/0036827 A1
(43) Pub. Date: Feb. 1, 2024

(54) COMPUTATION APPARATUS IN MEMORY CAPABLE OF COMPUTATION OF SIGNED WEIGHT

(71) Applicant: UIF (University Industry Foundation), Yonsei University, Seoul (KR)

(72) Inventors: Seong Ook JUNG, Seoul (KR); Dong Han KO, Seoul (KR); Young Kyu LEE, Seoul (KR); Se Hee LIM, Seoul (KR)

(73) Assignee: UIF (University Industry Foundation), Yonsei University, Seoul (KR)

(21) Appl. No.: 18/110,439

(22) Filed: Feb. 16, 2023

(30) Foreign Application Priority Data
Jul. 27, 2022 (KR) 10-2022-0093494

(51) Int. Cl. G06F 7/544; G11C 11/22

(52) U.S. Cl. CPC G06F 7/5443; G11C 11/223

(57) ABSTRACT

There is provided a computation apparatus located in a memory module and configured to perform computation with data stored in the memory, the computation apparatus including: a plurality of word lines to which an input is provided; a plurality of unit arrays which store a weight having a sign and perform a multiplication operation on the input provided from the word line and the weight; and an accumulation line connected to the plurality of unit arrays and on which results of the multiplication operations performed by the plurality of unit arrays are accumulated, wherein each of the plurality of unit arrays includes a source follower amplifier including a ferroelectric transistor configured to output a voltage corresponding to a result of the multiplication operation with respect to an input voltage provided to the word line.

### CROSS-REFERENCE TO RELATED APPLICATION

This application claims priority to Korean Patent Application No. 10-2022-0093494 (filed on Jul. 27, 2022), which is hereby incorporated by reference in its entirety.

### BACKGROUND

The technology relates to a computation apparatus in a memory for computation of signed weights.

In the conventional computation apparatuses, a memory for storing data and a computation apparatus for performing computation are separate from each other, and thus for computation, data stored in the memory is fetched and the fetched data is moved to the computation apparatus so that computation is performed, and then a computation result is moved back to the memory. According to the conventional computation apparatuses, such frequent data transfer causes a time delay, and significant power consumption is generated therefrom. In order to resolve this issue, a computation in-memory (CIM) structure that performs computation in a memory is proposed.

Meanwhile, neural networks are attracting attention. In neural networks, multiply and accumulate (MAC) computation, which is a multiplication operation of multiplying an input element by a weight element of a weight matrix and an accumulation operation of accumulating the multiplication results, needs to be performed. In a simple neural network, a neural network may be implemented using unsigned weight values.

However, according to a CIM structure adopting a non-volatile memory, upon a reboot after a power-off, it is required to read data from an external device in which data is stored, and store the data in the nonvolatile memory again to perform computation, and thus the data transfer causes a significant time delay, and power consumption occurs

Furthermore, when implementing a neural network, it is difficult to ensure the accuracy of using unsigned weights in a complex network, such as a convolution layer.

The embodiment is intended to resolve the above described issues of the related art. In other words, the embodiment is directed to providing an apparatus for a neural network computation in which a time delay occurring due to data transfer and power consumption are reduced while having high accuracy.

### SUMMARY

The present embodiment includes a computation apparatus located in a memory module and configured to perform computation with data stored in the memory, the computation apparatus including: a plurality of word lines to which an input is provided, a plurality of unit arrays which store a weight having a sign and perform a multiplication operation on the input provided from the word line and the weight, and an accumulation line connected to the plurality of unit arrays and on which results of the multiplication operations performed by the plurality of unit arrays are accumulated, wherein each of the plurality of unit arrays includes a source follower amplifier including a ferroelectric transistor configured to output a voltage corresponding to a result of the multiplication operation with respect to an input voltage provided to the word line.

According to an aspect of the present embodiment, the unit array includes a plurality of source follower amplifiers, a multiplication line connected to sources of the plurality of source follower amplifiers, and a transfer switch configured to control a connection between the multiplication line and the accumulation line.

According to an aspect of the present embodiment, a drain of the source follower amplifier is supplied with a predetermined voltage.

According to an aspect of the present embodiment, the ferroelectric transistor has a threshold voltage corresponding to the weight stored in the ferroelectric transistor, and the source follower amplifier outputs a voltage corresponding to a difference between the threshold voltage and a voltage corresponding to the provided input as a result of the multiplication operation to the multiplication line.

According to an aspect of the present embodiment, the computation apparatus further includes a pre-charge circuit configured to pre-charge the accumulation line with a pre-charge voltage, and when the input corresponds to a logic low, the transfer switch is turned on such that the voltage of the multiplication line is set to the pre-charge voltage.

According to an aspect of the present embodiment, the pre-charge voltage corresponds to a signed zero value.

According to an aspect of the present embodiment, the transfer switch is turned on after the multiplication operations of the plurality of unit arrays are completed to allow a voltage of the accumulation line to correspond to a result obtained by accumulating the results of the multiplication operations.

According to an aspect of the present embodiment, the computation apparatus further includes a discharge switch configured to discharge charges charged in the accumulation line to a reference voltage.

The present embodiment includes a unit array located in a memory module and configured to perform a multiplication operation with data stored in the memory, the unit array including: a plurality of word lines to which an input is provided; a multiplication line from which a result of a multiple operation is output; and a plurality of source follower amplifiers composed of a ferroelectric transistor including a drain to which a predetermined voltage is provided, a gate to which the input is provided, and a source for outputting a result of a multiplication operation of the weight value and the input to the multiplication line, wherein the source follower amplifier outputs a difference between the input and a threshold voltage of the ferroelectric transistor as the result of the multiplication operation.

According to an aspect of the present embodiment, the plurality of source follower amplifiers store different pieces of weight information as different threshold voltages.

According to an aspect of the present embodiment, an input is provided to one of the plurality of word lines, and the source follower amplifier provided with the input outputs the result of the multiplication operation.

According to an aspect of the present embodiment, the unit array further includes an accumulation line connected to the multiplication line and on which the multiplication result is accumulated, and one or more unit arrays connected to the accumulation line, wherein results of multiplication operations of the one or more unit arrays are accumulated on the accumulation line.

According to the embodiment, an apparatus for a neural network computation in which a time delay occurring due to data transfer and power consumption are reduced while having high accuracy can be provided.

### BRIEF DESCRIPTION OF THE DRAWINGS

FIG. 1 is a circuit diagram illustrating an example of a computation apparatus including a unit array according to the present embodiment.

FIGS. 2A and 2B are diagrams for describing an operation of a ferroelectric memory transistor, and FIG. 2C is a schematic diagram illustrating a current-to-voltage relationship of a ferroelectric memory transistor in a first state and a second state.

FIG. 3 is a schematic timing diagram for describing an operation of a computation apparatus according to the present embodiment.

FIG. 4 is a schematic circuit diagram for describing an operation of a computation apparatus in a first phase.

FIG. 5 is a schematic circuit diagram for describing an operation of a computation apparatus in a second phase.

FIG. 6 is a schematic circuit diagram for describing an operation of a computation apparatus in a third phase.

FIG. 7 is a diagram illustrating an example of an experiment result of a computation apparatus according to the present embodiment.

### DETAILED DESCRIPTION

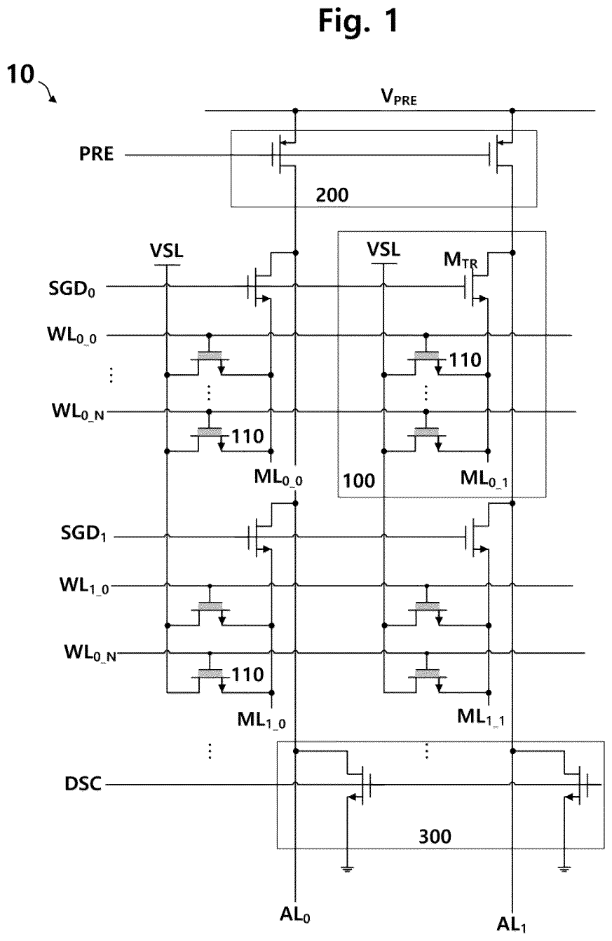

Hereinafter, the present embodiment will be described with reference to the accompanying drawings. FIG. 1 is a circuit diagram illustrating an example of a computation apparatus including a unit array according to the present embodiment. Referring to FIG. 1, a computation apparatus 10 is located in a memory module and performs computation with data stored in the memory. The computation apparatus 10 includes a plurality of word lines WL_{0_0}, . . . , WL_{0_N}, WL_{1_0}, . . . , and WL_{1_N} to which an input is provided, a plurality of unit arrays 100 for storing a weight with a sign (a signed weight) and performing a multiplication operation between an input provided from the word line and the weight, and accumulation lines A_{L0} and A_{L1} which are connected to the plurality of unit arrays 100 and on which results of multiplication operations performed by the plurality of unit arrays 100 are accumulated, and each of the plurality of unit arrays 100 includes a source follower amplifier 110 including a ferroelectric transistor that outputs a voltage corresponding to a result of a multiplication operation with respect to an input voltage provided to the word lines WL_{0_0}, . . . , WL_{0_N}, WL_{1_0}, . . . , and WL_{1_N}.

In one embodiment, the computation apparatus 10 further includes a pre-charge circuit 200. The pre-charge circuit 200 includes a pre-charge transistor that is turned on with a pre-charge signal PRE to pre-charge the accumulation lines AL₀ and AL₁ with a pre-charge voltage V_{PRE}. In the embodiment shown in FIG. 1, the pre-charge circuit 200 is illustrated as including a P-channel metal oxide semiconductor (PMOS) transistor, but in other embodiments (not shown), the pre-charge circuit may be implemented as an N-channel metal oxide semiconductor (NMOS) transistor.

In one embodiment, the computation apparatus 10 further includes a discharge circuit 300. The discharge circuit 300 is turned on with a discharge signal DSC to flows charges charged in the accumulation lines AL₀ and AL₁ to a reference potential VSS to discharge the accumulation lines AL₀ and AL₁. The unit array 100 includes a source follower amplifier 110 composed of plurality of ferroelectric transistors, and a drain of the ferroelectric transistor included in the source follower amplifier 110 is supplied with a preset voltage VSL, and a gate of the ferroelectric transistor is connected to a word line WL_{0_0}, . . . , WL_{0_N}, WL_{1_0}, . . . , or WL_{1_N} to receive an input. In one embodiment, the preset voltage VSL may be a VDD voltage. A source of the ferroelectric transistor is connected to a multiplication line ML_{0_0}, ML_{0_1}, ML_{1_0}, or ML_{1_1} and outputs a voltage corresponding to a result of a multiplication of the input provided through the gate and the weight stored in the ferroelectric transistor.

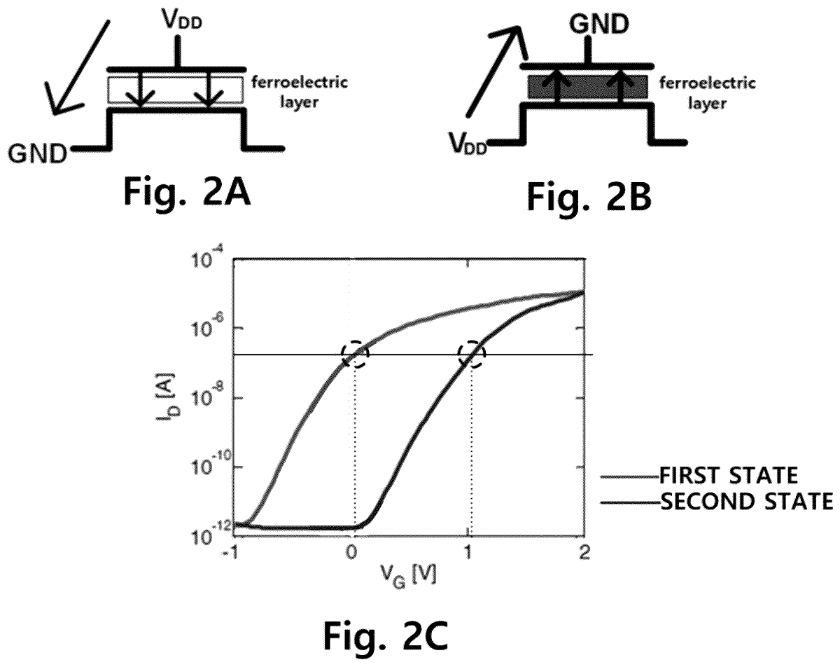

FIGS. 2A and 2B are diagrams for describing an operation of a ferroelectric memory transistor, and FIG. 2C is a schematic diagram illustrating a current-to-voltage relationship of a ferroelectric memory transistor in a first state and a second state. Referring to FIGS. 2A and 2B, the ferroelectric memory transistor includes a source, a drain, and a gate stack. The gate stack may include a gate oxide, a ferroelectric layer, and a gate electrode that are sequentially stacked.

The ferroelectric layer may be formed of a ferroelectric material. The ferroelectric material is a material that spontaneously polarizes and forms dipoles even when an electric field is not applied from the outside. When the ferroelectric material is supplied with a voltage greater than or equal to a critical voltage, dipoles formed in the ferroelectric layer are aligned according to a direction of the electric field. In addition, when the ferroelectric material is supplied with an opposite voltage greater than or equal to a critical voltage, the dipoles formed in the ferroelectric layer are aligned according to a direction of the electric field that is formed in the opposite direction. In FIGS. 2A and 2B, the polarization direction of the dipoles in the ferroelectric layer is indicated by an arrow, in which the head of the arrow is a positive pole of the dipole and the tail of the arrow is a negative pole of the dipole.

Referring to FIG. 2A, one of a source electrode and a drain electrode of the ferroelectric transistor is supplied with a ground voltage GND, and the other is electrically kept in a floating state. When a voltage greater or equal to a critical voltage is applied to a gate electrode, dipoles formed in the ferroelectric layer are aligned according to the direction of the electric field.

Orienting positive poles of dipoles toward a substrate brings about an effect similar to that of a decrease in a threshold voltage of a transistor. Thus, in a case in which an electric field is applied such that a sufficiently large number of positive poles of dipoles are oriented toward the substrate, a channel is formed between the source and the drain even when a voltage lower than a voltage in a second state is supplied through the gate electrode, which is indicated by a red diagram shown in FIG. 2C. Such a first state has an effect similar to that of a decrease in the threshold voltage of the transistor.

Referring to FIG. 2B, one of a source electrode and a drain electrode of the ferroelectric transistor is supplied with a driving voltage VDD greater than or equal to a critical voltage, and the other is electrically kept in a floating state. When a ground voltage GND is applied to a gate electrode, dipoles formed in the ferroelectric layer are aligned according to the direction of the electric field.

Orienting negative poles of dipoles toward a substrate brings about an effect similar to that of an increase in a threshold voltage of a transistor. Thus, in a case in which an electric field is applied such that a sufficiently large number of negative poles of dipoles are oriented toward the substrate, a higher voltage needs to be supplied in the second state compared to the voltage supplied to the gate electrode in the first state in order to flow the same current as that in the first state, which is indicated by a blue diagram shown in FIG. 2C. Such a second state has an effect similar to that of an increase in the threshold voltage of the transistor.

Examples of FIGS. 2A to 2C illustrate that the same two ferroelectric transistors are programmed to have two different thresholds, but ferroelectric transistors may be programmed to have a plurality of different thresholds. In the example illustrated in FIG. 1, the ferroelectric transistors included in the source follower amplifiers 110 included in the same unit array 100 may be programmed to have a plurality of different threshold voltages.

Referring to FIG. 1 again, the plurality of ferroelectric transistors included in the unit array 100 have a configuration of a source follower amplifier 110. The drain of the ferroelectric transistor is provided with a predetermined voltage, and the gate is provided with an input corresponding to a logic low or a logic high through the word line WL_{0_0}, . . . , WL_{0_N}, WL_{1_0}, . . . , and WL_{1_N}.

The source follower amplifier 110 outputs a voltage corresponding to a difference between the input voltage provided to the gate and the threshold voltage to a source. Such a voltage relationship is expressed as the following equation.

V_{O}−V_{∈}−V_{TH} [Equation 1]

(Vo: an output voltage of a source follower amplifier, V_{IN}: an input voltage of a source follower amplifier, V_{TH}: a threshold voltage)

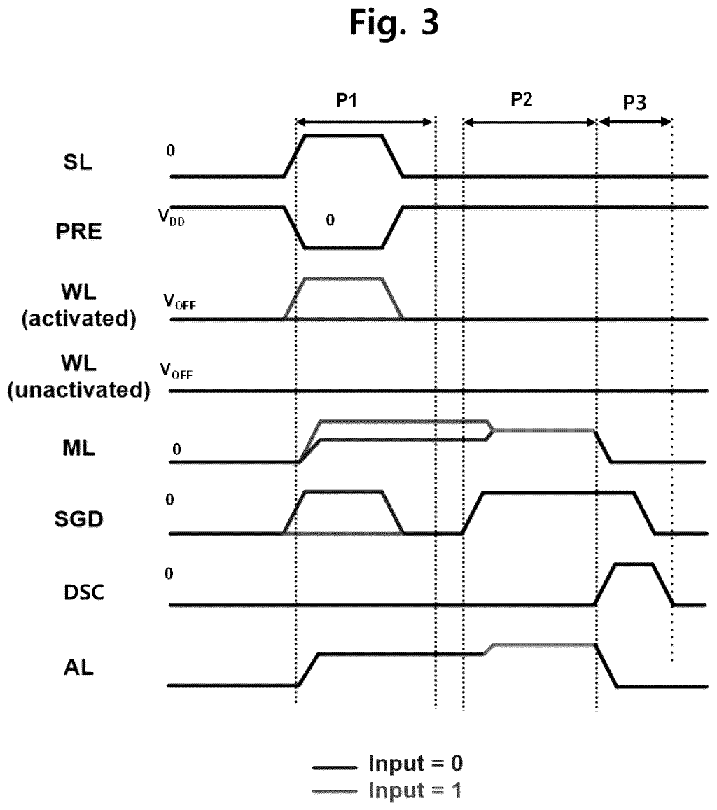

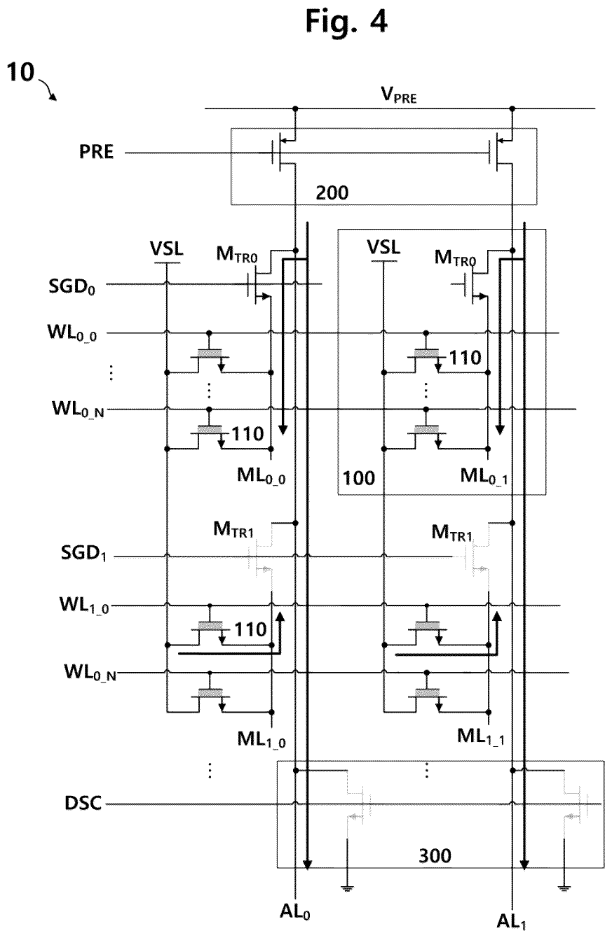

FIG. 3 is a schematic timing diagram for describing an operation of a computation apparatus 10 according to the present embodiment. FIG. 4 is a schematic circuit diagram for describing an operation of a computation apparatus 10 in a first phase. Referring to FIGS. 3 to 4, an operation of the embodiment in the first phase is described.

The computation apparatus 10 according to the present embodiment may operate in a first phase P1 in which each of the unit arrays performs a multiplication operation on an input and a weight and a second phase P2 in which the results computed in the first phase P1 are accumulated. As an embodiment, the computation apparatus 10 according to the present embodiment may further include a third phase P3 in which the accumulated accumulation line is discharged to initialize the operation results.

In the first phase P1, a preset voltage VSL is provided to the drains of the source follower amplifiers 110 included in the unit array 100. The drains of the source follower amplifiers 110 included in the computation apparatus 10 may all be electrically connected, and the voltage provided in the first phase P1 may be a voltage of VDD, which is a driving voltage of the computation apparatus 10.

A pre-charge signal PRE is provided to turn a pre-charge transistor on. As the pre-charge transistor is turned on, the accumulation lines A_{L0} and A_{L1} are pre-charged with a pre-charge voltage V_{PRE}.

An input is provided to a unit array 100 through one of a plurality of word lines connected to the unit array 100. In the embodiment shown in FIGS. 3 and 4, an input of 0 is provided through the word lines WL_{0_0}, . . . , and WL_{0_N} and an input of 1 is provided through the word line WL_{1_0}.

Each of the ferroelectric transistors of the source follower amplifiers 110 included in the unit array 100 stores a threshold voltage corresponding to a different weight value. Therefore, the source follower amplifier 110 connected to the word line through which an input is provided outputs a voltage corresponding to the difference between the input voltage and the threshold voltage to the source electrode.

Table 1 is a table that illustrates, when ferroelectric transistors store threshold voltages corresponding to a signed weight of 3 bits, multiplication results of an input and a weight and voltages of the multiplication line formed by the source follower amplifier 110.

TABLE 1

| Input | Weight | | |
|---|---|---|---|
| (1-bit) | (Signed 3-bit) | Input × Weight | ML voltage |
| 0 | −4 | 0 | V_{PRE} |
| | −3 | | (=V_{G} − V_{TH}_4) |
| | −2 | | |
| | −1 | | |
| | 0 | | |
| | 1 | | |
| | 2 | | |
| | 3 | | |
| 1 | −4 | −4 | V_{G} − V_{TH}_0 |
| | −3 | −3 | V_{G} − V_{TH}_1 |
| | −2 | −2 | V_{G} − V_{TH}_ 2 |
| | −1 | −1 | V_{G} − V_{TH}_3 |
| | 0 | 0 | V_{PRE} (=V_{G} − V_{TH}_4) |
| | 1 | 1 | V_{G} − V_{TH}_5 |
| | 2 | 2 | V_{G} − V_{TH}_6 |
| | 3 | 3 | V_{G} − V_{TH}_7 |

Referring to Table 1, the operation results of a signed weight and an input are indicated as V_{G}−V_{TH_0}, V_{G}−V_{TH_1}, V_{G}−V_{TH_2}, V_{G}−V_{TH_3}, V_{G}−V_{TH_4}, V_{G}−V_{TH_5}, V_{G}−V_{TH_6}, and V_{G}−V_{TH_7}. Among the results, an operation result of “0” corresponds to a voltage of V_{G}−V_{TH_4}, which is not a ground potential as in the conventional technology but a pre-charge voltage V_{PRE}.

A logic low voltage corresponding to a digital bit “0” may be provided through the word line WL_{0_0}, . . . , or WL_{0_N} as an input, in which case, an operation result of an input and a weight is 0, regardless of the weight value. When an input provided through the word line is 0, a transfer transistor M_{TR0} is turned on with a transfer signal SGD₀, and the multiplication lines ML_{0_0} and ML_{0_1} are pre-charged with a pre-charge voltage V_{PRE}, which is a voltage corresponding to the operation result, that is, 0.

A logic high voltage corresponding to a digital bit “1” is provided through the word line WL_{1_0} as an input. A transfer transistor M_{TR1} is blocked with a transfer signal SGD₁. The source follower amplifier 110 outputs a voltage corresponding to a multiplication operation result of a digital bit “1” and a weight value. The voltage corresponding to the multiplication result is indicated as V_{G}−V_{TH_0}, V_{G}−V_{TH_1}, V_{G}−V_{TH_2}, V_{G}−V_{TH_3}, V_{G}−V_{TH_4}, V_{G}−V_{TH_5}, V_{G}−V_{TH_6}, and V_{G}−V_{TH_7}, each of which corresponds to the difference between the input voltage provided to the word line and the threshold voltage programmed in the ferroelectric transistor.

Therefore, the multiplication lines ML_{1_0} and ML_{1_0} connected to the outputs of the source followers 110 provided with the logic high voltage corresponding to the digital bit “1” as an input are pre-charged with a voltage corresponding to the multiplication results by the source follower amplifiers 110.

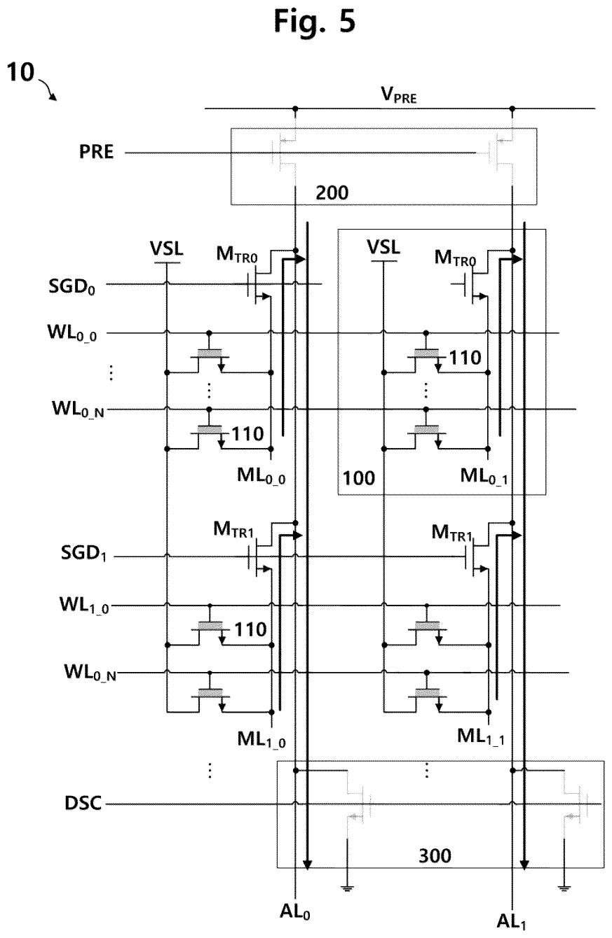

FIG. 5 is a schematic circuit diagram for describing an operation of a computation apparatus 10 in a second phase. Referring to FIGS. 3 and 5, an operation of the embodiment in the second phase is described. In the second phase, a reference voltage is provided to the drains of the source follower amplifiers 110 included in the unit array 100. Since the accumulation line AL, which is pre-charged in the second phase P2, may not accumulate the multiplication operation results, a pre-charge signal PRE is provided such that the pre-charge transistor is blocked.

Subsequently, transfer signals SGD₀ and SGD₁ are provided to turn the transfer transistors M_{TR} on. As the transfer transistors M_{TR} are turned on, charges charged in the multiplication line ML_{0_0} and the multiplication line ML_{1_0} are transferred to the accumulation line AL₀ and thus charge-shared, and charges charged in the multiplication line ML_{0_1} and the multiplication line ML_{1_1} are transferred to the accumulation line AL₁ and thus charge-shared.

As the charge sharing is performed, charges having been present in each of the multiplication lines are redistributed to each of the accumulation lines AL₀ and AL₁ to form a new voltage, and the voltage newly formed in the accumulation line corresponds to a result obtained by accumulating a multiplication result. Thus, as the voltage formed in the accumulation line AL₀ or AL₁ in the second phase P2 is detected, a multiply and accumulate (MAC) operation result may be obtained.

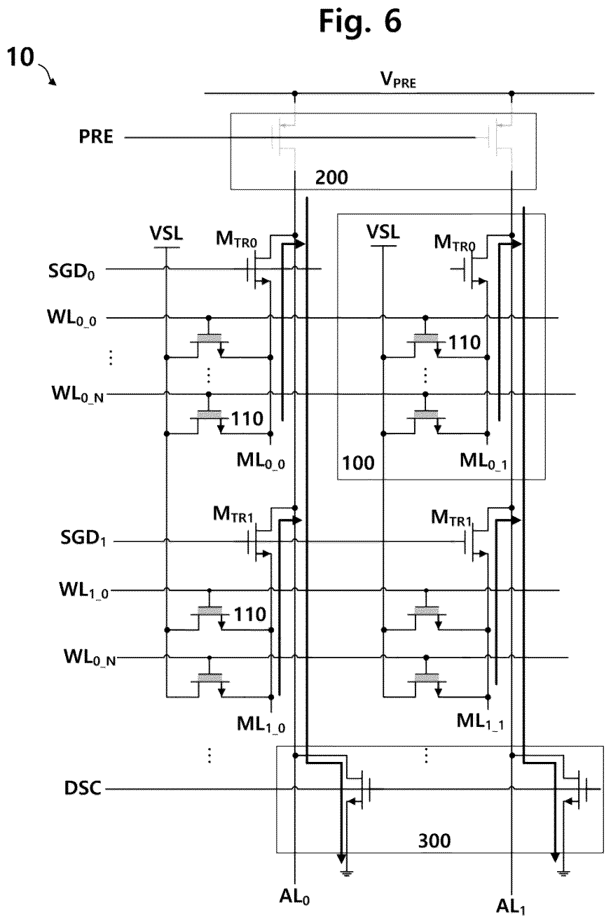

FIG. 6 is a view for describing a discharge phase P3. Referring to FIGS. 3 and 6, in the discharge phase P3 after completion of the second phase P2, a discharge signal DSC is provided to drive a discharge circuit 300, and charges charged in the accumulation lines AL₀ and AL₁ are discharged to the ground potential, and the voltage formed on the accumulation line may be formed as a reference potential.

In addition, as shown in FIG. 3, in the discharge phase P3, a section in which the discharge circuit 300 operates may overlap a section in which the transfer transistor is turned on.

Thus, charges charged in the multiplication line ML may also be transferred to the accumulation line in the discharge phase P3 and discharged together.

Experiment Result

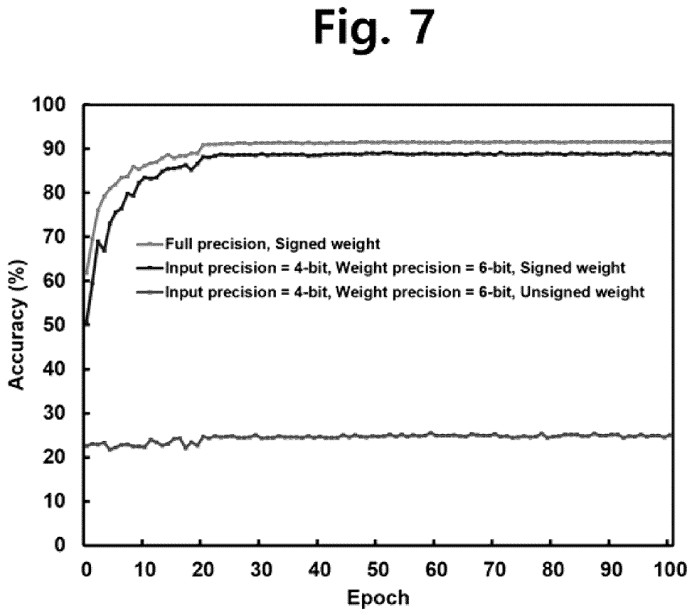

FIG. 7 is a diagram illustrating an example of an experiment result of a computation apparatus according to the present embodiment. Referring to FIG. 7, an inference experiment was conducted with a VGG-8 network and a CIFAR-10 data set. When an experiment was performed with signed weights, an inference accuracy of 88.71% was obtained as shown in the experiment result in FIG. 7, and it can be seen that the inference accuracy has greatly improved in comparison with an inference accuracy of 25% obtained with unsigned weights.

The present embodiment provides a benefit of reducing area consumption compared to the related art using two transfer transistors or an ReRAM and STT-MRAM by constructing a unit array with one transfer transistor and N ferroelectric transistors, and provides a benefit of increasing the accuracy in complex networks and/or data sets by performing computation using signed weights.

Although embodiments of the present invention have been described with reference to the accompanying drawings, this is for illustrative purposes, and those of ordinary skill in the art should appreciate that various modifications, equivalents, and other embodiments are possible without departing from the scope and sprit of the present invention. Therefore, the scope of the present invention is defined by the appended claims of the present invention.

1. A computation apparatus located in a memory module and configured to perform computation with data stored in the memory, the computation apparatus comprising:
a plurality of word lines to which an input is provided;
a plurality of unit arrays which store a weight having a sign and perform a multiplication operation on the input provided from the word line and the weight; and
an accumulation line connected to the plurality of unit arrays and on which results of the multiplication operations performed by the plurality of unit arrays are accumulated,
wherein each of the plurality of unit arrays includes a source follower amplifier including a ferroelectric transistor configured to output a voltage corresponding to a result of the multiplication operation with respect to an input voltage provided to the word line.

2. The computation apparatus of claim 1, wherein the unit array includes:
a plurality of source follower amplifiers;
a multiplication line connected to sources of the plurality of source follower amplifiers; and
a transfer switch configured to control a connection between the multiplication line and the accumulation line.

3. The computation apparatus of claim 2, wherein a drain of the source follower amplifier is supplied with a predetermined voltage.

4. The computation apparatus of claim 2, wherein the ferroelectric transistor has a threshold voltage corresponding to the weight stored in the ferroelectric transistor, and
the source follower amplifier outputs a voltage corresponding to a difference between the threshold voltage and a voltage corresponding to the provided input as a result of the multiplication operation to the multiplication line.

5. The computation apparatus of claim 2, wherein the computation apparatus further comprises a pre-charge circuit configured to pre-charge the accumulation line with a pre-charge voltage, and
when the input corresponds to a logic low, the transfer switch is turned on such that the voltage of the multiplication line is set to the pre-charge voltage.

6. The computation apparatus of claim 5, wherein the pre-charge voltage corresponds to a signed zero value.

7. The computation apparatus of claim 2, wherein the transfer switch is turned on after the multiplication operations of the plurality of unit arrays are completed to allow a voltage of the accumulation line to correspond to a result obtained by accumulating the results of the multiplication operations.

8. The computation apparatus of claim 1, further comprising a discharge switch configured to discharge charges charged in the accumulation line to a reference voltage.

9. A unit array located in a memory module and configured to perform a multiplication operation with data stored in the memory, the unit array comprising:
a plurality of word lines to which an input is provided;
a multiplication line from which a result of a multiple operation is output; and
a plurality of source follower amplifiers composed of a ferroelectric transistor including a drain to which a predetermined voltage is provided, a gate to which the input is provided, and a source for outputting a result of a multiplication operation of the weight value and the input to the multiplication line,
wherein the source follower amplifier outputs a difference between the input and a threshold voltage of the ferroelectric transistor as the result of the multiplication operation.

10. The unit array of claim 9, wherein the plurality of source follower amplifiers store different pieces of weight information as different threshold voltages.

11. The unit array of claim 9, wherein an input is provided to one of the plurality of word lines, and the source follower amplifier provided with the input outputs the result of the multiplication operation.

12. The unit array of claim 9, further comprising an accumulation line connected to the multiplication line and on which the multiplication result is accumulated, and
one or more unit arrays connected to the accumulation line,
wherein results of multiplication operations of the one or more unit arrays are accumulated on the accumulation line.
